(19) United States
(12) Patent Application Publication
(10) Pub. No.: US 2004/0240173 A1
(43) Pub. Date: Dec. 2, 2004

(54) Both-side-slot riser card

(75) Inventors: Chieh-Shih Yi, Taipei City (TW); Rong-Tay Chang, Taipei City (TW)

Correspondence Address: BACON & THOMAS, PLLC, 625 SLATERS LANE, FOURTH FLOOR, ALEXANDRIA, VA, 22314

(73) Assignee: Tatung Co., Ltd., Taipei (TW)

(21) Appl. No.: 10/654,955

(22) Filed: Sep. 5, 2003

(30) Foreign Application Priority Data
May 30, 2003 (TW) 92209999

(51) Int. Cl. H05K 7/00; H05K 5/00; H05K 7/14; G06F 1/16; H05K 7/18

(52) U.S. Cl. 361/686

(57) ABSTRACT

A both-side-slot riser card structure includes a riser card vertically mounted on a bracket and corresponding to a slot of a motherboard of a computer. Two card slots are respectively mounted on two opposite lateral surfaces of the riser card for receiving a horizontally placed adapter. The horizontal placement of adapters economizes the use of space within the computer so that more adapters can be installed in a computer that has small inner space. Further, the bracket on which the both-side-slot riser card structure is mounted is substantially integrated with the chassis so as to enhance the structural stability of the computer.

### FIELD OF THE INVENTION

The present invention relates to computer adapter adaptors, more particularly to a both-side-slot riser card utilized in personal computers or servers having small inner space.

### BACKGROUND OF THE INVENTION

For simultaneously connecting with a variety of peripheral devices, the motherboard of a personal computer includes a plurality of adapter slots.

However, the inner space of a small computer, such as that of an 1U server, is so limited that it cannot contain adapters of regular heights. To put a number of adapters in such a computer, the chassis thereof must be enlarged, which will increases the volume and the weight of the computer and violates the principle of computer miniaturization.

Therefore, it has become a task for computer engineers to include a plurality of adapters into a computer having tiny inner space.

### SUMMARY OF THE INVENTION

Accordingly, the primary object of the present invention is to provide a both-side-slot riser card so that more adapters can be connected within computers having tiny inner space.

It is a further object of the present invention that the bracket on which the both-side-slot riser card is mounted forms a part of the computer chassis frame, so as to enhance the structural toughness thereof.

To achieve the above objects, the present invention provides a both-side-slot riser card to be mounted within a computer that includes a chassis frame, a motherboard mounted on the chassis frame, and at least one slot vertically mounted on the motherboard and has a connecting port facing upright.

The both-side-slot riser card correspondingly adapted to one aforementioned slot and comprises a bracket, a riser card, and at least two card slots. The riser card is vertically mounted on the bracket and correspondingly inserted into the slot on the motherboard. The card slots are respectively mounted on two opposite lateral surfaces of the riser card, and each has a connecting port facing to an opposite direction parallel to the motherboard

Further, each of the card slots on the riser card may receive a horizontally inserted adapter. The horizontal placement of adapters economizes the use of space within the computer so that more adapters can be installed in a computer that has small inner space.

Moreover, a plurality of escape holes is formed on the bracket, and same number of corresponding screw holes is formed on the chassis frame. A plurality of screws is used to lock the bracket onto the chassis frame, by which the bracket becomes an integral part of the chassis and enhances the structural stability of the computer.

The various objects and advantages of the present invention will be more readily understood from the following detailed description when read in conjunction with the appended drawing.

### BRIEF DESCRIPTION OF THE PREFERRED DRAWINGS

FIG. 1 is a perspective view of the present invention utilized in a computer.

FIG. 2 is an exploded perspective view of the present invention utilized in a computer.

FIG. 3 is an exploded view of the present invention.

FIG. 4 is an exploded view of the present invention from another perspective.

FIG. 5 is a perspective view of the present invention from another perspective.

### BRIEF DESCRITPTION OF THE PREFERRED EMBODIMENTS

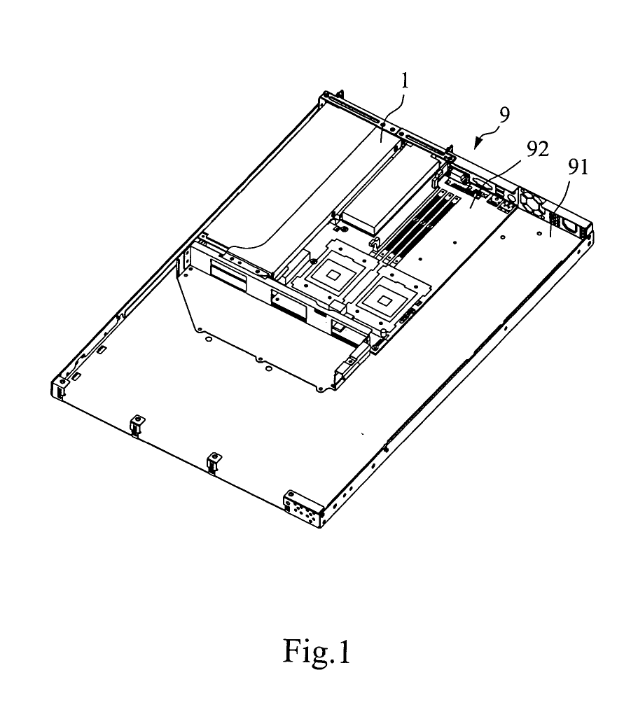

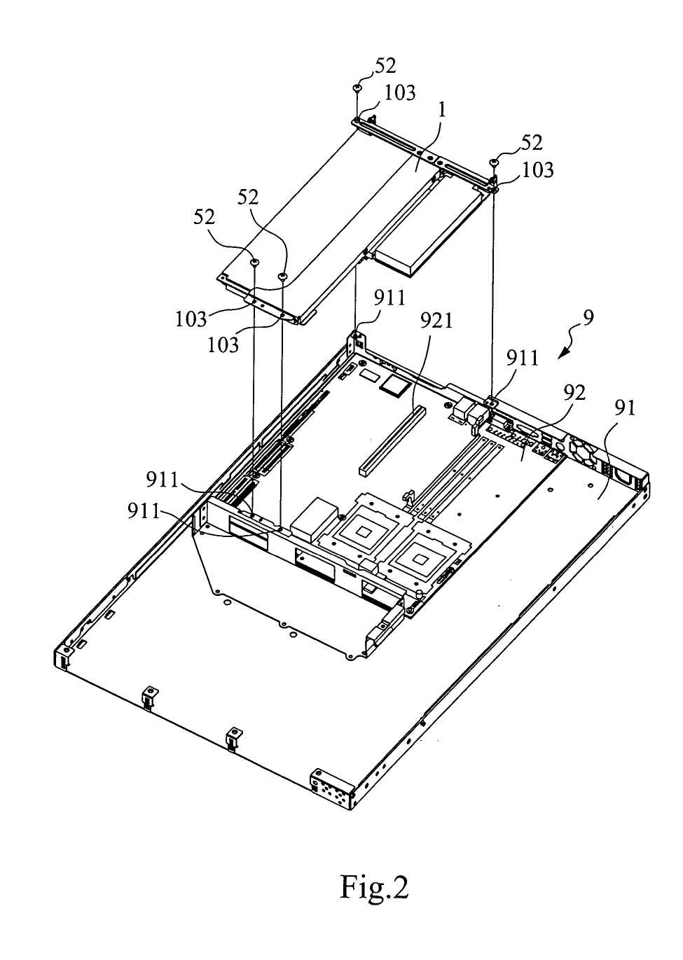

Referring to FIG. 1, which is a perspective view of a preferred embodiment of the present invention used in a computer, a short and flat computer 9 (a server, for example) comprises a chassis frame 91 and a motherboard 92. Now referring to FIG. 2, which is a perspective view of the preferred embodiment in decomposed configuration, the motherboard 92 is mounted on the chassis frame 91, and a slot 921 vertically mounted on the motherboard 92 and having a connecting port facing upright.

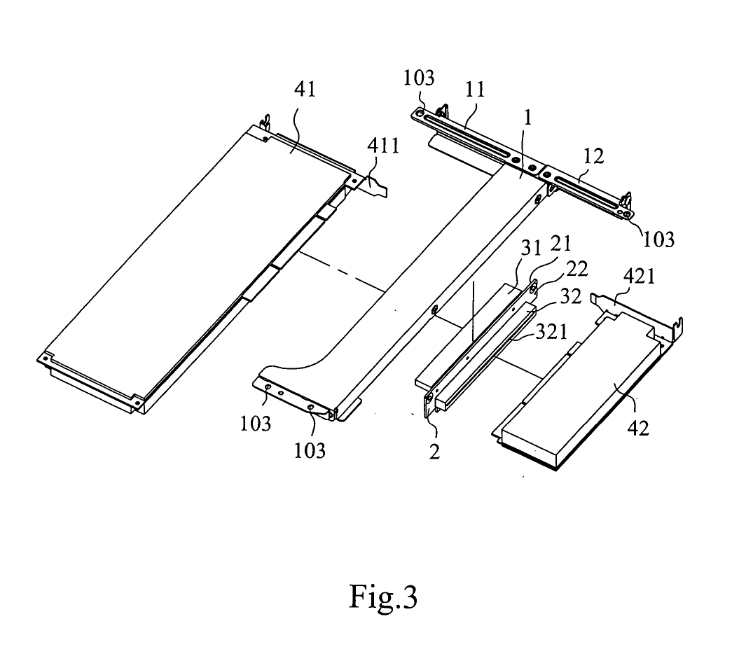

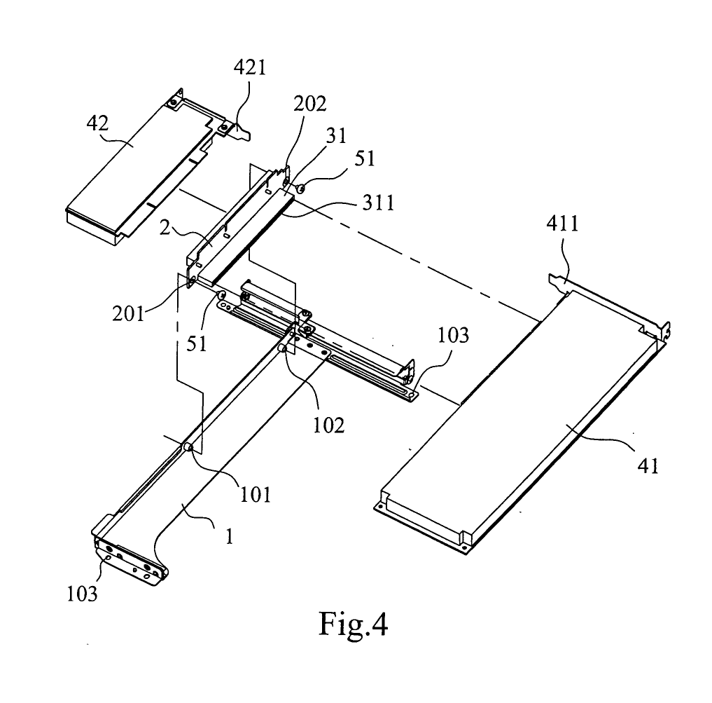

Referring to FIG. 1, FIG. 2, FIG. 3 (an exploded view of the present invention), and FIG. 4 (a turn-around exploded view of the present invention), the present invention as a both-side-slot riser card correspondingly adapted to the slot 921 of the motherboard 92 comprises a bracket 1, a riser card 2, a long card slot 31, and a short card slot 32. The bracket 1 is mounted on the chassis frame 91 of the computer 9 by screwing a plurality of escape holes 103 on the bracket 1 onto a plurality of corresponding screw holes 911 on the chassis frame 91 using a plurality of screws 52. Since the bracket 1 is substantially mounted on the chassis frame 91, it actually forms an integral part of the chassis frame 91, which enhances the structural stability thereof.

To fix the riser card 2 to the bracket 1, two locking holes 201, 202 formed on the riser card 2 are aligned with corresponding locking bosses 101,102 formed on the bracket 1, and then two screws 51 are used to screw the locking bosses 101,102 and the locking holes 201,202 together. Further, the riser card 2 is inserted into the slot 921 of the motherboard 92 so that the long-card connecting port 311 of the long card slot 31 and the short-card connecting port 321 of the short card slot 32 respectively face to an opposite direction parallel to the motherboard 92.

As shown in those figures, the both-side-slot riser card further includes a long profile adapter 41 and a short profile adapter 42, respectively correspondingly connected to the long card slot 31 and the short card slot 32.

Therefore, the horizontal placement of the long profile adapter 41 and the short profile adapter 42 into respectively the long card slot 31 and the short card slot 32 significantly economizes the use of space within a small, flat computer, as the one in FIG. 1, which increases the number of adapters that may be contained in the computer.

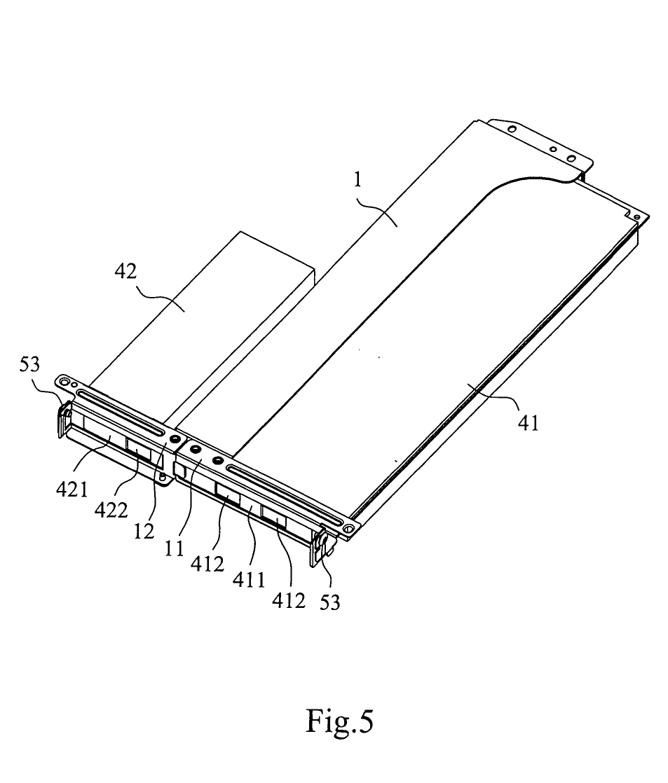

Referring to FIG. 5, which is a perspective view of the preferred embodiment in assembled configuration, a long lateral frame 11 and a short lateral frame 12 respectively extends from an end of the bracket 1 in opposite directions. The above-mentioned long profile adapter 41 includes a long card cover 411, which is fixed to the long lateral frame 11 by a screw 53. The short profile adapter 42 includes a short card cover 421, which is fixed to the short lateral frame 12 by another screw 53. Notice that, in this preferred embodiment, the short card cover 421 of the short profile adapter 42 is piled on the outer surface of the long card cover 411 of the long profile adapter 41, which is the better way to align those two card covers. If, instead, the long card cover 411 of the long profile adapter 41 piles on the outer surface of the short card cover 421 of the short profile adapter 42, it would easily happen that the long card cover 411 shelters the connect port opening 422 on the short card cover 421. It is a further advantage that the piling up of those card covers not only economizes the use of space but also eliminates possible electromagnetic interferences (EMI).

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A both-side-slot riser card mounted within a computer, said computer includes a chassis frame, a motherboard mounted on said chassis frame, and at least one slot vertically mounted on said motherboard and having a connecting port facing upright; said both-side-slot riser card correspondingly adapted to one said slot and comprising:
a bracket;
a riser card, vertically mounted on said bracket, and correspondingly inserted into said slot of said motherboard; and
at least two card slots being respectively mounted on two opposite lateral surfaces of said riser card and respectively having a connecting port facing to an opposite direction parallel to said motherboard.

2. The both-side-slot riser card of claim 1, wherein said at least two card slots include a long card slot correspondingly connected with a long profile adapter.

3. The both-side-slot riser card of claim 2, wherein a long lateral frame extends laterally from one end of said bracket, and said long profile adapter includes a long card cover mounted on said long lateral frame.

4. The both-side-slot riser card of claim 1, wherein said at least two card slots include a short card slot correspondingly connected with a short profile adapter.

5. The both-side-slot riser card of claim 4, wherein a short lateral frame extends laterally from one end of said bracket, and said short profile adapter includes a short card cover mounted on said short lateral frame.

6. The both-side-slot riser card of claim 1, wherein two locking bosses are formed on said bracket, and two locking holes corresponding to said locking bosses are formed on said riser card; two screws being used to vertically mount said riser card on said bracket by attaching said locking holes to said locking bosses.

7. The both-side-slot riser card of claim 1, wherein a plurality of escape holes is formed on said bracket, and same number of corresponding screw holes is formed on said chassis frame; a plurality of screws being used to lock said bracket onto said chassis frame by connecting said escape holes and said screw holes.
